(19) United States
(12) Patent Application Publication
(10) Pub. No.: US 2005/0136640 A1
(43) Pub. Date: Jun. 23, 2005

(54) Die exhibiting an effective coefficient of thermal expansion equivalent to a substrate mounted thereon, and processes of making same

(76) Inventors: Chuan Hu, Chandler, AZ (US); Steven Towle, Sunnyvale, CA (US); Anna George, Sunnyvale, CA (US)

Correspondence Address: SCHWEGMAN, LUNDBERG, WOESSNER & KLUTH, P.A., P.O. BOX 2938, MINNEAPOLIS, MN, 55402, US

(21) Appl. No.: 10/956,621

(22) Filed: Sep. 30, 2004

Related U.S. Application Data
(63) Continuation-in-part of application No. 10/036,389, filed on Jan. 7, 2002, now Pat. No. 6,841,413.

(51) Int. Cl. H01L 21/44

(52) U.S. Cl. 438/612

(57) ABSTRACT

A thinned die is disposed on a heat sink and bonded by a thermal interface material (TIM) that includes a gold-tin solder. The thinned die exhibits a die-effective coefficient of thermal expansion (CTE) that substantially matches the CTE of the heat sink. A process of bonding the die includes thermal bonding. A process of bonding the thinned die to a heat sink before bonding the die to an electrical interposer. A computing system includes a semconductive die that is gold-tin bonded to the heat sink, and it is coupled to at least one input-output device.

### RELATED APPLICATIONS

This application is a Continuation-In-Part of U.S. patent application No. 10/036,389, filed on Jan. 7, 2002, the disclosure of which is incorporated herein by specific reference.

### TECHNICAL FIELD

Disclosed embodiments relate to packaging a semiconductor die to produce integrated circuits.

### BACKGROUND

Higher performance, lower cost, increased miniaturization of integrated circuit components and greater packaging density of integrated circuits are ongoing goals of the computer industry. As these goals are achieved, semiconductor dies become smaller and the power consumption/density becomes higher.

Generally the surface area provided by the active surface for most semiconductor dice does not provide enough surface for all of the external contacts needed to contact external devices for certain types of semiconductor dice. Additional surface area can be provided with the use of an interposer, such as a substantially rigid material or a substantially flexible material.

One problem arising from the fabrication of a smaller semiconductor die is that the density of power consumption of the integrated circuit components in the semiconductor die has increased, which, in turn, increases the average junction temperature of the die. If the temperature of the semiconductor die becomes too high, the integrated circuits of the semiconductor die may be damaged or destroyed and the lifetime/reliability of chips drops significantly. Furthermore, for semiconductor dice of equivalent size, the overall power increases which presents the same problem of increased power density.

Various apparatus and techniques have been used for removing heat from semiconductor dice. Some techniques involve the use of encapsulation materials to encapsulate semiconductor dice on to a heat spreader, or to embed (secure) semiconductor dice into recesses (cavities) within a heat spreader for heat dissipation. The use of these techniques produces additional, complicated processing steps for fabricating an integrated circuit package and the thermal performance of these assembly methods is limited by the materials and processes. Therefore, it would be advantageous to develop new apparatus and techniques for integrated circuit fabrication that eliminates complicated processing steps and the necessity of the substrate interposer, and provides improved heat dissipation.

The coefficient of thermal expansion (CTE) of materials proximate a die is also a problem. Destructive stresses can develop between a board and the die due to the intrinsic difference of material properties (Si with CTE or 2.6 ppm/C and substrate with CTE of 16 ppm/C). The thermal/mechanical stress issue is even worse when microelectronic device package generates significant heat. This also limits the choices of low dielectric constant materials which are needed for high performance devices.

### BRIEF DESCRIPTION OF THE DRAWINGS

In order to understand the manner in which embodiments are obtained, a more particular description of various embodiments briefly described above will be rendered by reference to the appended drawings. These drawings depict embodiments that are not necessarily drawn to scale and are not to be considered to be limiting in scope. Some embodiments will be described and explained with additional specificity and detail through the use of the accompanying drawings in which:

FIG. 1 is a cross-sectional elevation of a chip package according to an embodiment;

FIG. 2A is a cross-sectional elevation of a chip package during processing according to an embodiment;

FIG. 2B is a cross-sectional detail of the chip package depicted in FIG. 2A during further processing according to an embodiment;

FIG. 3 is a cross-sectional elevation of a chip package according to an embodiment;

FIG. 4 is a cross-sectional elevation of a chip package according to an embodiment;

FIG. 5 is a process flow diagram according to an embodiment; and

FIG. 6 is a depiction of a computing system according to an embodiment.

### DETAILED DESCRIPTION

The following description includes terms, such as upper, lower, first, second, etc. that are used for descriptive purposes only and are not to be construed as limiting. The embodiments of a device or article described herein can be manufactured, used, or shipped in a number of positions and orientations. The terms “die” and “processor” generally refer to the physical object that is the basic workpiece that is transformed by various process operations into the desired integrated circuit device. A die is usually singulated from a wafer, and wafers may be made of semiconducting, non-semiconducting, or combinations of semiconducting and non-semiconducting materials.

A board is typically a conductor-overlay structure that is insulated and that acts as a mounting substrate for the die. A board is usually singulated from a board array. Reference will now be made to the drawings wherein like structures will be provided with like reference designations. In order to show the structure and process embodiments most clearly, the drawings included herein are diagrammatic representations of embodiments. Thus, the actual appearance of the fabricated structures, for example in a photomicrograph, may appear different while still incorporating the essential structures of embodiments. Moreover, the drawings show only the structures necessary to understand the embodiments. The embodiment may be referred to, individually and/or collectively, herein by the term, “invention” merely for convenience and without intending to voluntarily limit the scope of this disclosure to any single invention or inventive concept if more than one is in fact disclosed. Additional structures known in the art have not been included to maintain the clarity of the drawings.

In accordance with disclosed embodiments, the formation of a thinned semiconductor die attached to a planar heat spreader, and in combination with a substrate produces a number of qualities for an integrated circuit package. One characteristic of an embodiment includes the heat spreader may be planar (as opposed to irregular, non-planar shapes), which allows for easier fabrication. Another characteristic of an embodiment includes easier attachment of the die to the heat spreader as compared to “die embedded-in-heat spreader” techniques since precise control of depositing material in the bottom of a cavity is not necessary, which is particularly advantageous for a self-aligned solder approach. Another characteristic of an embodiment is that no encapsulation of the die to the heat spreader is required as with other techniques. Another characteristic of an embodiment includes bonding the thinned die with a bump onto the Cu heat spreader before attaching the Si die onto an organic substrate. Another characteristic of an embodiment includes using a thin hard solder with a higher remelting temperature to attach the thinned Si die and the Cu heat spreader together.

Additionally, the thinned die reduces the thermal resistance of the die/heat spreader combination to improve heat extraction from the die. The thinned die also is more compliant such that it expands and contracts in concert with the thermal/mechanical properties of the heat spreader, thus reducing stress-induced cracking at the interface between Si die and Cu heat spreader. With the strong coupling from Cu heat spreader to raise the effective CTE of Si, the stress between the Si die and the organic substrate is also significantly reduced.

Although the figures illustrate various embodiments, these figures are not meant to portray integrated circuit (microelectronic) packages in precise detail. Rather, these figures illustrate integrated circuit packages in a manner to more clearly convey enumerated embodiments and their equivalents. Additionally, elements common between the figures may retain the same numeric designation.

Embodiments include a packaging technology that places one or more thinned semiconductor (microelectronic) dies on a planar heat sink and secures the semiconductor dies on to the heat sink by a hard adhesive thermal interface material. In an embodiment, the die may be attached to the heat sink using an adhesive material such as a solder material. Alternative methods of forming a bond between the die and the heat sink may also be used.

These embodiments enable the integrated circuit package to be built around the thinned semiconductor die. The configurations also result in thinner form factors, as the die is very thin and a smaller heat sink is needed for the package, according to an embodiment.

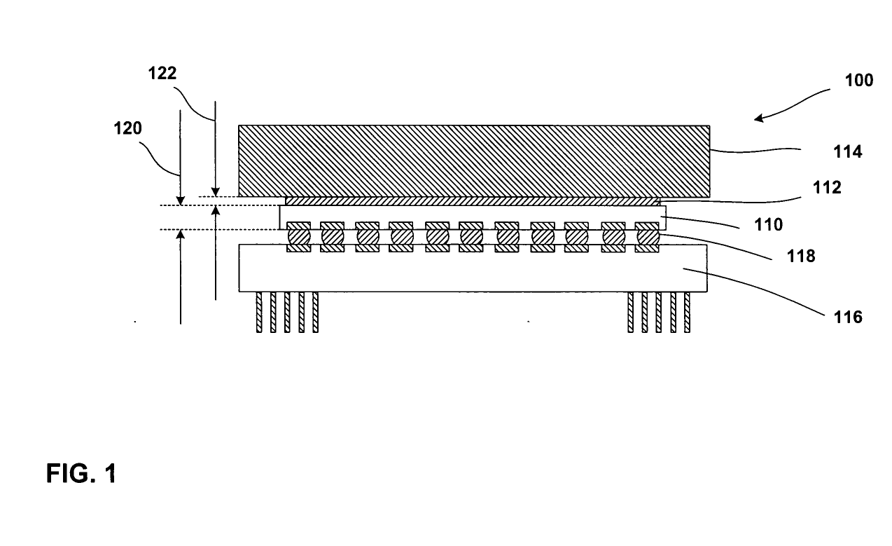

FIG. 1 is a cross-sectional elevation of a chip package 100 according to an embodiment. A thinned die 110 is depicted bonded with a thermal interface material (TIM) 112 to a heat sink 114 before the front (active) side of the thinned die 110 is bonded to a substrate 116 such as an organic interposer. The interconnect structure 117, which is on the front side of the thinned die 110, is coupled to the substrate 116 through a series of electrical bumps, one of which is designated with reference numeral 118.

In an embodiment, the thinned die 110 has a thickness 120 in a range from about 20 micrometer (μm) to about 150 μm. In an embodiment, the thinned die 110 has a thickness 120 in a range from about 80 μm to about 120 μm. In an embodiment, the thinned die 110 has a thickness 120 of about 100 μm. In an embodiment, the thinned die 110 has a thickness 120 of no more than about 100 μm. In an embodiment, the thinned die 110 has a thickness 120 of less than about 100 μm.

In an embodiment, the TIM 112 has a bond-line thickness (BLT) 122 in a range from about 0.1 μm to about 50 μm. In an embodiment, the TIM 112 has a BLT 122 in a range from about 0.5 μm to about 40 μm. In an embodiment, the TIM 112 has a BLT 122 in a range from about 1 μm to about 30 μm. In an embodiment, the TIM 112 has a BLT 122 in a range from about 2 μm to about 20 μm. In an embodiment, the TIM 112 has a BLT 122 in a range from about 5 μm to about 10 μm. In an embodiment, the TIM 112 has a BLT 122 of about 6 μm.

FIG. 1 also illustrates the heat sink 114 used to fabricate an integrated circuit package 100 in accordance with various embodiments. The heat sink 114 includes a substantially planar (flat), highly thermally conductive material to remove the power dissipated in the thinned die 110.

In an embodiment, the material used to fabricate the heat sink 114 includes a metal such as copper, copper alloys including copper alloys with tungsten, copper laminates, copper diamond, cladded copper structures, combinations thereof, and the like. In an embodiment, the material used to fabricate the heat sink 114 includes molybdenum, molybdenum laminates, molybdenum alloys, cladded molybdenum structures, combinations thereof, and the like. In an embodiment, the material used to fabricate the heat sink 114 includes aluminum, aluminum alloys including metallized aluminum nitride, aluminum diamond, cladded aluminum structures, combinations thereof, and the like. The aluminum nitride may be metallized with chromium/gold, titanium/gold, or nickel/gold films. In an embodiment, the material used to fabricate the heat sink 114 includes beryllium oxide and the like. In an embodiment, the material used to fabricate the heat sink 114 includes carbon fibers, graphite, diamond, combinations thereof, and the like. In an embodiment, the material used to fabricate the heat sink 114 includes, but is not limited to, thermally conductive ceramic materials, such as AlSiC, AlN, and the like.

The coefficient of thermal expansion (CTE) of the material of the heat sink 114 is selected to minimize crack-inducing stresses in the thinned die 110, particularly the edge of die 112 at the interconnect 117 on die and in the bump 118. For example, by closely matching the CTE of the heat sink 114 material (e.g., AlSiC) to silicon, incidents of stress-induced die cracking may be reduced. For example, by matching the CTE of the heat sink material 114 with the organic interposer 116 (e.g. Cu), the stress between the interconnect 117 and electrical bump 118 may be reduced. In an embodiment for the thinned die 110, the heat sink 114 is made of materials (e.g., copper) of larger CTE mismatch to silicon (an exemplary semiconductor die material) without causing stress-induced die cracking. Also, the heat sink 114 can be formed of materials with a close CTE match to a substrate 116 upon which the thinned die 110 may be placed for operation (e.g., a central processing unit (CPU) for a computer). The thinness of the thinned die 110 allows it to conform to the thermally-induced dimensional changes of the heat sink 114.

In an embodiment, the thinned die 110 is part of a package 100 that forms an article. The article includes the heat sink 114 including a heat sink-characteristic CTE that is based upon its material and mode of construction. The thinned die 110 is disposed on the heat sink 114. The thinned die 110 includes a die-characteristic CTE. The TIM 112 bonds the thinned die 110 to the heat sink, and constitutes one embodiment of the article, without the substrate 116. Because of the thickness of the thinned die 110 as set forth in this disclosure, the thinned die 110 includes a die-effective CTE that is greater than the die-characteristic CTE. In other words, the die-effective CTE substantially matches the heat sink-characteristic CTE.

In an embodiment, the article that is part of the package 100 includes a die-effective CTE that is greater than the die-characteristic CTE in a range from about two times to about five times. In an embodiment, the exact die-effective CTE substantially matches the heat sink-characteristic CTE. In an embodiment, the die-effective CTE is in a range from about 10 ppm/° C. to about 17 ppm/° C. In an embodiment the die-effective CTE is about 16.2 ppm/° C.

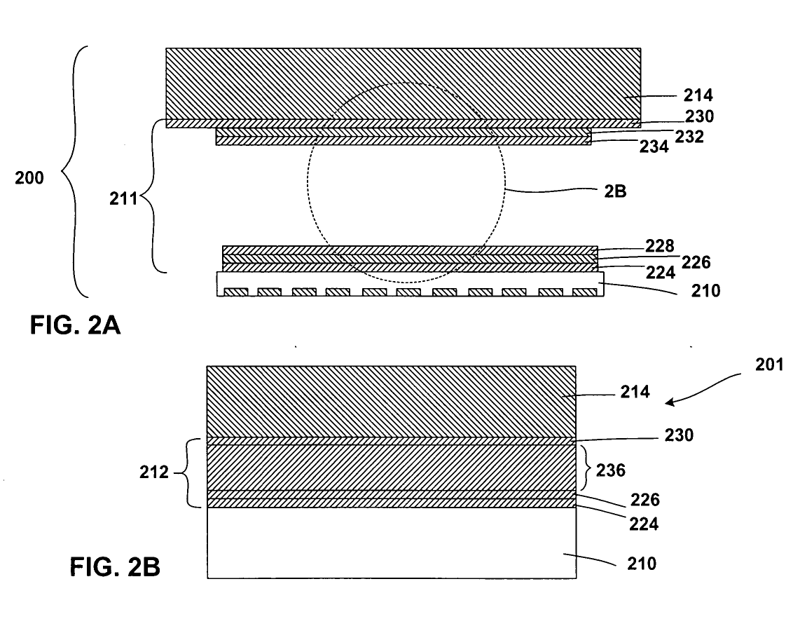

FIG. 2A is a cross-sectional elevation of a chip package 200 during processing according to an embodiment. The chip package 200 represents an intermediate structure during assembly. A thinned die 210, including each of the thinness embodiments set forth in this disclosure, is depicted being assembled with thermal interface materials (TIMs) 211 to a heat sink 214.

Before the die 210 is bonded to the heat sink 214, the die 210 is thinned according to an embodiment. The thickness of the die 210 is reduced according to one or more of various techniques such as, grinding, chemical mechanical polishing, plasma etching, or other techniques, according to an embodiment. In an embodiment, chemical etching is used to reduce the thickness of the die 210. In an embodiment, grinding is used to reduce the thickness of the die 210. In an embodiment, polishing is used to reduce the thickness of the die 210. In an embodiment, any two of the above techniques are used to reduce the thickness of the die 210. In an embodiment, any three of the above techniques are used to reduce the thickness of the die 210. In an embodiment, all of the above techniques are used to reduce the thickness of the die 210.

In an embodiment, the heat sink 214 is substantially copper. In an embodiment, the TIMs 211 include a nickel cladding layer 230 disposed on the heat sink 214, a gold layer 232 disposed on the nickel cladding layer 230, and a tin layer 234 disposed on the gold layer 232. In a embodiment, the TIMs 211 include a titanium cladding layer 224 disposed on the thinned die 210, a nickel-vanadium layer 226 disposed on the titanium cladding layer 224, and a gold bottom layer 228 disposed on the nickel-vanadium layer 226.

Selection of the layer thicknesses includes consideration of a final BLT that relates to the BLT 122 depicted in FIG. 1. In an embodiment, the heat sink 214 is substantially copper. In an embodiment, the nickel cladding layer 230 is in a thickness range from about 0.05 μm to about 0.6 μm. In an embodiment, the nickel cladding layer 230 is in a thickness range from about 0.1 μm to about 0.45 μm. In an embodiment, the nickel cladding layer 230 is about 0.3 μm. In an embodiment, the gold layer 232 is in a thickness range from about 0.5 μm to about 6 μm. In an embodiment, the gold layer 232 is in a thickness range from about 1 μm to about 4 μm. In an embodiment, the gold layer 232 is about 3 μm. In an embodiment, the tin layer 234 is in a thickness range from about 0.05 μm to about 0.6 μm. In an embodiment, the tin layer 234 is in a thickness range from about 0.1 μm to about 0.15 μm. In an embodiment, the tin layer 234 is about 0.3 μm.

In an embodiment, the titanium cladding layer 224 is in a thickness range from about 0.05 μm to about 0.2 μm. In an embodiment, the titanium cladding layer 224 is in a thickness range from about 0.075 μm to about 0.15 μm. In an embodiment, the titanium cladding layer 224 is about 0.1 μm. In an embodiment, the nickel-vanadium layer 226 is in a thickness range from about 0.05 μm to about 0.6 μm. In an embodiment, the nickel-vanadium layer 226 is in a thickness range from about 0.1 μm to about 0.15 μm. In an embodiment, the nickel-vanadium layer 226 is about 0.3 μm. In an embodiment, the gold bottom layer 228 is in a thickness range from about 0.05 μm to about 0.2 μm. In an embodiment, the gold bottom layer 228 is in a thickness range from about 0.075 μm to about 0.15 μm. In an embodiment, the gold bottom layer 228 is about 0.1 μm.

In an embodiment, the heat sink 214 is substantially copper, the nickel cladding layer 230 is about 3 μm, the gold layer 232 is about 3 μm, the tin layer 234 is about 3 μm, the titanium cladding layer 224 is about 0.1 μm, the nickel-vanadium layer 226 is about 0.3 μm, and the gold bottom layer 228 is about 0.1 μm.

FIG. 2B is a cross-sectional detail of the chip package 200 depicted in FIG. 2A during further processing according to an embodiment. The cross-sectional detail is taken from the section line 2B in FIG. 2A, and the chip package 200 in FIG. 2A has been brought together. The chip package 201 is depicted as a bonded article that includes a TIM 212. FIG. 2 illustrates a view of a single thinned die 210 attached (mounted) with an adhesive (TIM) 212 to the heat sink 214. In an embodiment, a thermal bonding machine (such as thermal compressive bonder, reflow oven) is used to attach the thinned die 210 to the heat sink 214.

With several of the TIM embodiments, a fluxless bonding process is carried out. For example, a fluxless bonding process is carried out with a copper heat sink 214 and a substantially silicon thinned die 210. The thinned die 210 is about 50 μm thick, and the TIM 212, when finished bonding, is about 6 μm thick. In the fluxless bonding process, the titanium cladding layer 224 is about 0.1 μm, the nickel-vanadium layer 226 is about 0.3 μm, and the gold bottom layer 228 is about 0.1 μm. Additionally in the fluxless bonding process, the nickel cladding layer 230 is about 3 μm, the gold layer 232 is about 3 μm, and the tin layer 234 is about 3 μm. Bonding is carried out by melting the tin layer 234 at its solidus temperature, (T_{solidusSn}), and further heating. In an embodiment, bonding is carried out by the instant chip joining process generally known in the art for e.g. titanium and/or chromium with silicon, but the bonding process is applied as part of the thinned die processing embodiment of this disclosure.

The TIM 212 allows heat to be transferred by conduction from the thinned die 210 to the heat sink 214. In an embodiment, the TIM 212 includes a gold-tin-nickel zone 236 that is formed by the fusion of portions of the nickel cladding layer 230, the gold layer 232, tin layer 234, the nickel-vanadium layer 226, and the gold bottom layer 228. Although the gold-tin-nickel zone 236 is depicted in FIG. 2B with distinct lines of demarcation between the nickel cladding layer 230 and the nickel-vanadium layer 226, processing can create a diffusion gradient that approaches significantly pure nickel at the remnant of the nickel cladding layer 230, and a nickel-vanadium zone at the remnant of the nickel-vanadium layer 226. Processing intensities including processing times and temperatures can alter the diffusion gradient.

In an embodiment, the gold-tin-nickel zone 236 includes the gold and the tin in a ratio from about 60:40 to about 80:20. In this embodiment, the amount of nickel is in a range from about 1 ppm to about one-half the total of the gold-tin-nickel. In an embodiment, the gold and the tin are in a ratio of about 70:30. In this embodiment, the amount of nickel is in a range from about 1 ppm to about one-half the total of the gold-tin-nickel. The specific ratio of the gold and the tin in the gold-tin-nickel zone 236 depends upon starting conditions and processing conditions.

In an embodiment, processing conditions during assembly of the chip package 201 include pressing the heat sink 214 and its layers 230, 232, and 234 into the thinned die 210 along with its layers 224, 226, and 228. Processing also includes thermal bonding under conditions to reach the T_{solidusSn} in the tin layer 234. As the T_{solidusSn} is reached and surpassed, the tin begins to melt and form an eutectic with the gold in the various layers including the gold layer 232 and the gold bottom layer 228. Additionally, some of the nickel is also drawn into what becomes the gold-tin-nickel zone 236.

In an embodiment, a process includes thinning a die 210, and bonding the die 210 to the heat sink 214. In an embodiment following bonding, the thinned die 210 exhibits a die-effective CTE that is greater than the die-characteristic CTE. In this process, the thinned die 210 includes a die-TIM precursor. The die-TIM precursor includes the titanium cladding layer 224 disposed on the thinned die 210, the nickel vanadium layer 226 disposed on the titanium cladding layer 224, and the gold bottom layer 228 disposed on the nickel-vanadium layer 226. The heat sink 214 includes a heat-sink-TIM precursor. The heat-sink-TIM precursor includes the nickel cladding layer 230 disposed on the heat sink 214, the gold layer 232 disposed on the nickel cladding layer 230, and the tin layer 234 disposed on the gold layer 232. After thermal bonding as set forth herein, the TIM 212 includes a thickness in a range from about 0.1 μm to about 50 μm.

According to an embodiment after bonding, the process forms a titanium zone 224 disposed above and on the thinned die 210, a nickel-vanadium zone 226 disposed on the titanium zone 224, the gold-tin-nickel zone 236 disposed on the nickel-vanadium zone 226, and a nickel zone 230 disposed on the gold-tin-nickel zone 236, which in turn is disposed on the heat sink 214.

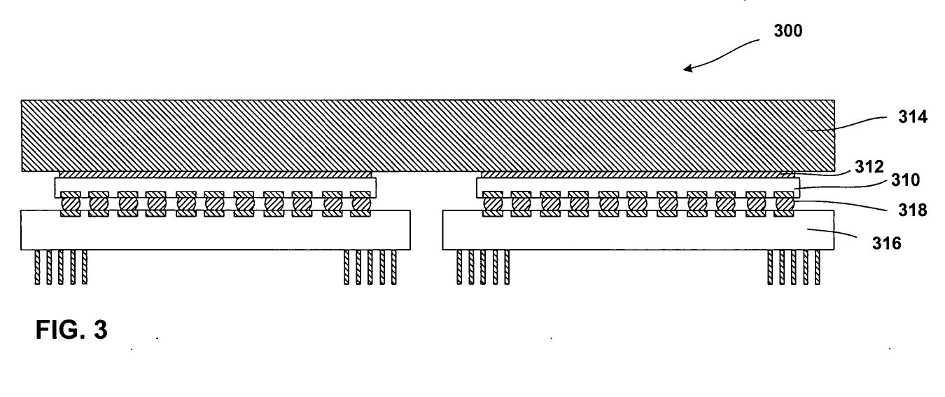

FIG. 3 is a cross-sectional elevation of a chip package 300 according to an embodiment. A plurality of thinned dice 310 are depicted bonded with a TIM 312 to a heat sink 314, and at the active surfaces of the thinned dice 310, to a plurality of substrates 316 such as an organic interposer. The thinned dice 310 are coupled to the substrates 316 through a series of electrical bumps, one of which is designated with reference numeral 318.

In an embodiment, the thinned dice 310 are substantially identical microelectronic devices, such as parallel processors manufactured by Intel Corporation of Santa Clara, Calif. In an embodiment, the thinned dice 310 are complementary microelectronic devices, such as at least a portion of a chipset manufactured by Intel Corporation.

In an embodiment, the thinned dice 310 are each a different thickness, whether the same thickness of a different thickness, or of a thickness of any of the embodiments set forth in this disclosure. In an embodiment, the BLT of the TIM 312 is of a thickness of any of the embodiments set forth in this disclosure, in combination with any of the thinned dice 310 thickness. Consequently, the die-effective CTE according to the several embodiments, is greater than the die-characteristic CTE by a factor of at least two, according to an embodiment. In an embodiment, the die-effective CTE is greater than the die-characteristic CTE by a factor of from about two to about five.

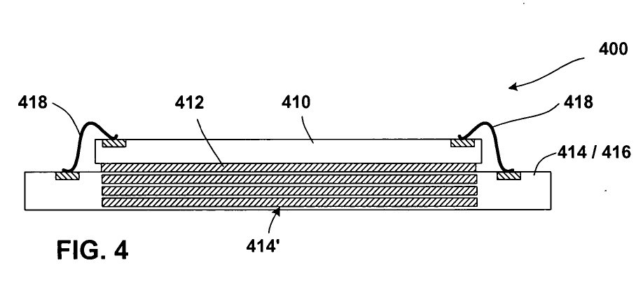

FIG. 4 is a cross-sectional elevation of a chip package 400 according to an embodiment. A thinned die 410 is depicted bonded with a TIM 412 to a heat sink 414 that is also the mounting substrate 416 such as an organic board made of metal-laminated fiber glass. The active surface of the thinned die 410 is coupled to the heat sink/substrate 414/416 through a series of wire bonds 418. A heat sink structure 414′ is depicted according to an embodiment, as a metal laminate that is metal-concentrated below the thinned die 410 and that is integral to the heat sink/substrate 414/416. In an embodiment, application of the chip package 400 is to a portable device such as a hand-held device or a notebook computer.

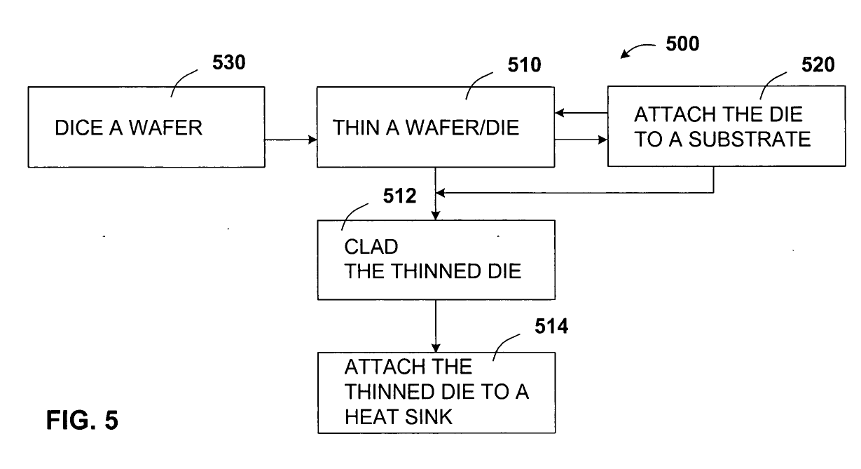

FIG. 5 is a process flow diagram 500 according to an embodiment.

At 510, the process includes thinning a wafer before dicing it into many dies or thinning a die after the die has already been cracked from a wafer. By way of non-limiting example, a die 210 is thinned according to any of the thinning process embodiments or their equivalents as set forth herein.

A process flow embodiment continues at 512 by cladding the thinned die. By way of non-limiting example, the thinned die 210 (FIG. 2A) is clad with the titanium cladding layer 224. Additionally, the process flow includes forming the nickel-vanadium layer 226 on the titanium cladding layer 224, and the gold bottom layer 228 on the nickel-vanadium layer 226. In an embodiment, a process flow is completed at 512.

At 514, a process flow continues by attaching the thinned die to a heat sink. By way of non-limiting example, the heat sink 214 (FIG. 2A) is prepared by forming the nickel cladding layer 230 on the heat sink 214. In an embodiment, forming the nickel cladding layer 230 on the heat sink 214 is carried out by a separate business entity and is not part of a claimed process embodiment. In any event, a gold layer 232 is formed on the nickel cladding layer 230, and a tin layer 234 is formed on the gold layer 232. In an embodiment, a process flow is completed at 514.

At 520, a process includes attaching a die to a substrate. By way of non-limiting example, a die 310 is attached to a substrate 316 such as an interposer. According to this process flow embodiment, a process flow is completed at 520.

At 530 a process flow embodiment includes dicing a wafer before thinning the wafer. In an embodiment, the process flow begins at 530 by wafer dicing, followed by the process at 510, which includes die thinning.

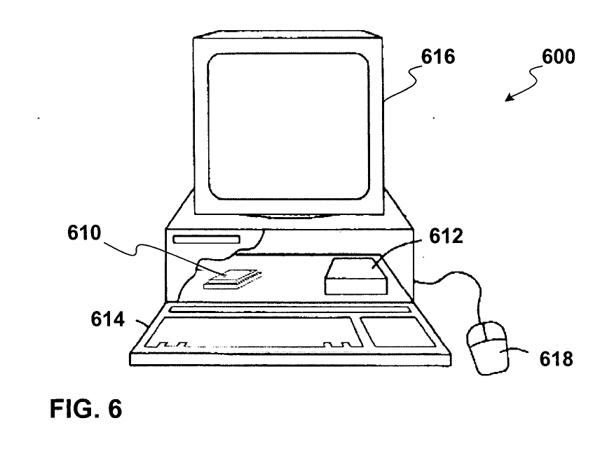

FIG. 6 is a depiction of a computing system 600 according to an embodiment. The computing system 600 includes a thinned die such as the thinned die 110 along with a TIM such as the TIM 112. Likewise, the computing system 600 includes a heat sink such as the heat sink 114. Hereinafter, where the computing system 600 refers to a thinned die, it is understood to include a TIM and a heat sink according to each of the various embodiments set forth in this disclosure. One or more of the foregoing embodiments of the thinned die configuration may be utilized in a computing system, such as a computing system 600 of FIG. 6. Similarly, the computing system can include a die, a gold-tin TIM, and a heat sink according to any of the article embodiments set forth in this disclosure.

In an embodiment, the computing system 600 includes at least one processor (not pictured), which is enclosed in a package 610, a data storage system 612, at least one input device such as keyboard 614, and at least one output device such as monitor 616, for example. The computing system 600 includes a processor that processes data signals, and may include, for example, a microprocessor, available from Intel Corporation. In addition to the keyboard 614, the computing system 600 can include another user input device such as a mouse 618, for example.

For purposes of this disclosure, a computing system 600 embodying components in accordance with the claimed subject matter may include any system that utilizes a thinned die embodiment, which may be coupled to a mounting substrate 620. The thinned die embodiment can also be coupled to the mounting substrate 620 for a die that contains a digital signal processor (DSP), a micro-controller, an application specific integrated circuit (ASIC), or a microprocessor.

For purposes of this disclosure, a computing system 600 embodying components in accordance with the claimed subject matter may include any system that utilizes a microelectronic device system, which may include, for example, a thinned die configuration that is coupled to data storage such as dynamic random access memory (DRAM), polymer memory, flash memory, and phase-change memory. In this embodiment, the thinned die configuration is coupled to any combination of these functionalities by being coupled to an input-output device. In an embodiment, however, a thinned die configuration set forth in this disclosure is coupled to any of these functionalities. For an example embodiment, data storage includes an embedded DRAM cache on a thinned die. Additionally in an embodiment, the thinned die configuration is part of the system with a thinned die configuration that is coupled to the data storage of the DRAM cache. Additionally in an embodiment, a thinned die configuration is coupled to the data storage 612.

In an embodiment, the computing system 600 can also include a thinned die that contains a digital signal processor (DSP), a micro controller, an application specific integrated circuit (ASIC), or a microprocessor. In this embodiment, the thinned die configuration is part of any combination of these functionalities by being coupled to a motherboard or the like. For an example embodiment, a DSP (not pictured) is part of a chipset that may include a stand-alone thinned die processor (in package 610) and the DSP as separate parts of the chipset. In this embodiment, a thinned die configuration, is part of the DSP package, and a separate thinned die configuration may be present that is part of the processor package 610. Additionally in an embodiment, a thinned die configuration is coupled to a DSP that is mounted on the same board 620 as the package 610.

It can now be appreciated that embodiments set forth in this disclosure can be applied to devices and apparatuses other than a traditional computer. For example, a die can be packaged with an embodiment of the thinned die configuration, and placed in a portable device such as a wireless communicator or a hand-held device such as a personal data assistant and the like. Another example is a thinned die that can be packaged as an embodiment and placed in a vehicle such as an automobile, a locomotive, a watercraft, an aircraft, or a spacecraft.

The Abstract is provided to comply with 37 C.F.R. §1.72(b) requiring an Abstract that will allow the reader to quickly ascertain the nature and gist of the technical disclosure. It is submitted with the understanding that it will not be used to interpret or limit the scope or meaning of the claims.

In the foregoing Detailed Description, various features are grouped together in a single embodiment for the purpose of streamlining the disclosure. This method of disclosure is not to be interpreted as reflecting an intention that the claimed embodiments of the invention require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separate preferred embodiment.

It will be readily understood to those skilled in the art that various other changes in the details, material, and arrangements of the parts and method stages which have been described and illustrated in order to explain the nature of this invention may be made without departing from the principles and scope of the invention as expressed in the subjoined claims.

1. An article comprising:
a semiconductive die;
a heat spreader; and therebetween
a thermal interface material including a gold-tin solder.

2. The article of claim 1, wherein the gold-tin solder is in a ratio of gold to tin from about 60:40 to about 80:20.

3. The article of claim 1, wherein the semiconductive die is fabricated with transistors and an interconnect structure, and wherein the die is bumped with a solder bump.

4. The article of claim 1, wherein the gold-tin solder is in a ratio of gold to tin from about 60:40 to about 80:20, and further including an additional metal in the thermal interface material.

5. The article of claim 1, wherein the gold-tin solder is in a ratio of gold to tin from about 60:40 to about 80:20, and further including nickel metal in the thermal interface material.

6. The article of claim 1, wherein the gold-tin solder is in a ratio of gold to tin from about 60:40 to about 80:20, and further including nickel metal in the thermal interface material, wherein the nickel is in a range from about 1 ppm to about one-half the total of the gold-tin-nickel thermal interface material.

7. The article of claim 1, wherein the gold-tin solder is in a ratio of gold to tin of about 70:30, and further including nickel metal in the thermal interface material, wherein the nickel is in a range from about 1 ppm to about one-half the total of the gold-tin-nickel thermal interface material.

8. The article of claim 1, wherein the semiconductive die includes an active surface and a backside surface, and further including a substrate, wherein the semiconductive die is disposed with the active surface coupled to the substrate through an electrical bump.

9. The article of claim 1, wherein the semiconductive die includes an active surface and a backside surface, and further including a substrate, wherein the semiconductive die is disposed with the active surface coupled to the substrate through an electrical bump, wherein the thermal interface material is in a thickness range from about 5 μm to about 50 μm, and wherein the semiconductive die is in a thickness range from about 50 μm to about 150 μm.

10. An article comprising:
a heat sink including a heat sink-characteristic coefficient of thermal expansion (CTE);
a die disposed on the heat sink including a die-characteristic CTE; and
a thermal interface material (TIM) which bonds the heat sink to the die, and wherein the die includes a die-effective CTE that is greater than the die-characteristic CTE.

11. The article of claim 10, wherein the die-effective CTE is greater than the die-characteristic CTE in a range from about two times to about five times.

12. The article of claim 10, wherein the die-effective CTE is in a range from about 10 ppm/° C. to about 17 ppm/° C.

13. The article of claim 10, wherein the die-effective CTE is about 16.2 ppm/° C.

14. The article of claim 10, wherein the TIM includes a gold-tin-nickel zone.

15. The article of claim 10, wherein the TIM includes a gold-tin-nickel zone, wherein the gold and the tin are present in a ratio from about 60:40 to about 80:20.

16. The article of claim 10, wherein the TIM includes a gold-tin-nickel zone, and wherein the TIM includes a thickness in a range from about 0.1 micron to about 50 micron.

17. The article of claim 10, wherein the die includes a thickness in a range from about 50 micron to about 150 micron.

18. The article of claim 10, wherein the die includes a first die and further including a second die disposed upon the heat sink, wherein the first die is a thinned die.

19. The article of claim 10, wherein the die includes a first die and further including a second die disposed upon the heat sink, wherein the first die is a thinned die, and wherein the second die is a thinned die.

20. An intermediate structure comprising:
a heat sink including a body, and a cladding layer disposed on the body;
a die including a thermal interface material (TIM) precursor, wherein the TIM precursor includes a titanium layer disposed on the die; a nickel vanadium layer disposed on the titanium layer; and a gold layer disposed on the nickel-vanadium layer.

21. The intermediate structure of claim 20, wherein the titanium layer is in a thickness range from about 0.05 micron to about 0.2 micron, wherein the nickel-vanadium layer is in a thickness range from about 0.15 micron to about 0.6 micron, and wherein the gold layer is in a thickness range from about 0.05 micron to about 0.2 micron.

22. The intermediate structure of claim 20, wherein the die includes a thickness in a range from about 50 micron to about 150 micron.

23. The intermediate structure of claim 20, wherein the die includes a thickness in a range from about 50 micron to about 150 micron, and wherein the die-effective coefficient of thermal expansion (CTE) is greater than the die-characteristic CTE in a range from about two times to about five times.

24. The intermediate structure of claim 20, wherein the die includes a thickness in a range from about 50 micron to about 150 micron, and wherein the die-effective CTE is in a range from about 10 ppm/° C. to about 17 ppm/° C.

25. The intermediate structure of claim 20, wherein the die includes a thickness in a range from about 50 micron to about 150 micron, and wherein the die-effective CTE is about 16.2 ppm/° C.

26. A computing system comprising:
a heat sink including a heat sink-characteristic coefficient of thermal expansion (CTE);
a die disposed on the heat sink including a die-characteristic CTE;
a thermal interface material (TIM), wherein the die includes a die-effective CTE that is greater than the die-characteristic CTE;
an interposer for the input and output of signal from the die; and
dynamic random access storage coupled to the die.

27. The computing system of claim 26, wherein the die exhibits a die-effective CTE that is about equal to the heat sink-characteristic CTE.

28. The computing system of claim 26, wherein the interposer is made of organic materials and copper lines.

29. The computing system of claim 26, wherein the die includes a thickness in a range from about 50 micron to about 150 micron.

30. The computing system of claim 26, wherein the die exhibits a die-effective CTE that is about equal to the heat sink-characteristic CTE, and wherein the die includes a thickness in a range from about 50 micron to about 150 micron.

31. The computing system of claim 26, wherein the computing system is disposed in one of a computer, a wireless communicator, a hand-held device, an automobile, a locomotive, an aircraft, a watercraft, and a spacecraft.

32. The computing system of claim 26, wherein the die is selected from a data storage device, a digital signal processor, a micro controller, an application specific integrated circuit, and a microprocessor.

33. A process comprising:
bonding a semiconductive die to a heat sink, wherein the semiconductive die is bonded to the heat sink with a gold-tin thermal interface material (TIM).

34. The process of claim 33, wherein bonding achieves a die-effective CTE that is greater than the die-characteristic CTE.

35. The process of claim 33, further including thinning the semiconductive die, including a technique selected from plasma etching, chemical etching, grinding, polishing, and combinations thereof.

36. The process of claim 33, further including thinning the semiconductive die to a thickness range from about 50 micron to about 150 micron.

37. The process of claim 33, wherein before bonding, the TIM includes a die-TIM precursor and a heat-sink-TIM precursor, wherein the die-TIM precursor includes a titanium layer disposed on the die; a nickel vanadium layer disposed on the titanium layer; and a gold layer disposed on the nickel-vanadium layer; and
wherein the heat-sink-TIM precursor includes a nickel layer disposed on the heat sink; a gold layer disposed on the nickel layer; and a tin layer disposed on the gold layer; and
wherein bonding includes forming a TIM thickness in a range from about 0.1 μm to about 50 μm.

38. The process of claim 33, wherein bonding forms a titanium zone disposed above and on the die, a nickel-vanadium zone disposed on the titantium zone, a gold-tin-nickel zone disposed on the nickel-vanadium zone, a nickel zone disposed on the gold-tin-nickel zone and also disposed on the heat sink.

39. The process of claim 33, wherein bonding a heat sink includes bonding a heat sink body with a cladding layer disposed on the heat sink body, wherein the cladding layer includes a nickel layer disposed on the heat sink body, a gold layer disposed on the nickel layer, and a tin layer on the gold layer.

40. The process of claim 33, wherein bonding a heat sink includes bonding a heat sink body with a cladding layer disposed on the heat sink body, wherein the cladding layer includes an about 0.3 μm nickel layer disposed on the heat sink body, an about 3 μm gold layer disposed on the nickel layer, and an about 0.3 μm tin layer on the gold layer.

41. The process of claim 33, further including bonding a thinned die to an interposer that has previously been attached to the heat sink.
